(19) United States
(12) Patent Application Publication
(10) Pub. No.: US 2026/0182225 A1
(43) Pub. Date: Jun. 25, 2026

(54) DISPLAY DEVICE

(71) Applicant: LG Display Co., Ltd., Seoul (KR)

(72) Inventors: YoungDock CHO, Paju-si (KR); YuRi KOH, Paju-si (KR); Kilyong SHIN, Paju-si (KR); Yerin YOON, Paju-si (KR)

(73) Assignee: LG Display Co., Ltd., Seoul (KR)

(21) Appl. No.: 19/219,169

(22) Filed: May 27, 2025

(30) Foreign Application Priority Data
Dec. 24, 2024 (KR) 10-2024-0196136

(51) Int. Cl. H10K 59/80; H10K 59/35

(52) U.S. Cl. CPC H10K 59/879; H10K 59/80521; H10K 59/352

(57) ABSTRACT

A display device may include a first display area and a second display area located outside the first display area. The second display area may have a lower light transmittance for light of a first wavelength than the first display area. The display device may further include a pixel electrode located in the first display area, a bank disposed on the pixel electrode and having a first opening exposing a portion of the pixel electrode, an emission layer disposed on the pixel electrode, a common electrode disposed on the emission layer, an encapsulation layer disposed on the common electrode, a light transmissive enhancement layer overlapping with the bank and the encapsulation layer and disposed between the bank and the encapsulation layer. At least a portion of the common electrode contacts the light transmissive enhancement layer. The display device can improve transmittance of light passing through the display panel.

### CROSS REFERENCE TO RELATED APPLICATION

This application claims the benefit of and priority to Korean Patent Application No. 10-2024-0196136, filed on Dec. 24, 2024 in the Korean Intellectual Property Office, the entire contents of which are incorporated herein by reference for all purposes as if fully set forth herein.

### BACKGROUND

### 1. Technical Field

The present disclosure relates to electronic devices, and more specifically, to display devices.

### 2. Description of Related Art

Display devices are widely used not only as televisions or monitors, but as display screens of various electronic devices, such as notebook computers, tablet computers, smart phones, portable display devices, portable information devices, and the like. As display technology advances, various types of display devices have been developed, such as a liquid crystal display (LCD) device, an organic light emitting diode (OLED) display device, an inorganic light emitting display device, a micro light emitting display device, a mini light emitting displays device, a quantum dot light emitting display device, and the like.

To meet various needs of users, display devices have been developed to provide increased functions, such as an image capture function, a sensing function, and the like, as well as an image display function. To provide these functions, display devices have been equipped with optical electronic devices, such as a camera, a sensor for detecting an image, a light receiving device, and the like.

To effectively receive light passing through the front surface of a display device, it may be desirable for such an optical electronic device to be located in an area of the display device where incident light coming through the front surface can be increasingly received and detected. However, when a camera or sensor is placed in a front portion of a display device, this configuration may impose limitations in designing the configuration of various elements included in the display device. To address this issue, work has been progressing on reducing a space occupied by a camera or sensor in the front portion of the display device, for example, forming a hole for an optical electronic device, displaying images on full screen, and the like.

The description of related art should not be considered prior art merely because it is mentioned in or associated with this section. The description of related art includes information that describes one or more aspects of the subject technology, and the description in this section does not limit the scope of the invention.

### SUMMARY

One or more aspects of the present disclosure may provide a display device including a light transmissive structure of enabling at least one electronic device located under, at a lower portion of, a display panel to effectively receive light (e.g., visible light, infrared light, ultraviolet light, or the like) while not being exposed in a front surface of the display device.

One or more aspects of the present disclosure may provide a display device including a light transmissive enhancement layer capable of increasing light transmittance even in an area of the common electrode where a hole is not present.

One or more aspects of the present disclosure may provide a display device including a structure of enabling a detection sensor located under, or at a lower portion of, a display panel to efficiently receive light while maintaining the characteristics of light emitting areas included in the display device.

One or more aspects of the present disclosure may provide a display device including a structure of enabling an infrared sensor located under, or at a lower portion of, a display panel to efficiently receive infrared light through an infrared transmissive layer, which is a type of light transmissive enhancement layer.

According to one or more example embodiments of the present disclosure, a display device can be provided that includes a substrate, and a display area configured to display an image. The display area may include a first display area and a second display area located outside of the first display area, and the second display area may have a lower light transmittance for light of a first wavelength than the first display area. The display device may further include a pixel electrode disposed on the substrate and located in the first display area, a bank disposed on the pixel electrode and having a first opening exposing a portion of the pixel electrode, an emission layer disposed on the pixel electrode, a common electrode disposed on the emission layer, an encapsulation layer disposed on the common electrode, a light transmissive enhancement layer overlapping with the bank and the encapsulation layer and disposed between the bank and the encapsulation layer. In one or more aspects, at least a portion of the common electrode may contact the light transmissive enhancement layer.

According to one or more example embodiments of the present disclosure, a display device can be provided that includes a substrate, a common electrode disposed on a substrate, and an infrared transmissive layer disposed on the substrate, overlapping with at least a portion of the common electrode, and having a greater infrared transmittance than the common electrode. In one or more aspects, the display device may include a display area configured to display an image, and the display area may include a first display area in which a common electrode hole is formed, and a second display area located outside of the first display area and not having the common electrode hole. In one or more aspects, the first display area may include light emitting areas including light emitting elements, and the infrared transmissive layer may be disposed in the first display area and have a first opening overlapping with a corresponding one of the light emitting areas.

According to one or more aspects of the present disclosure, a display device may be provided that includes a light transmissive structure of enabling at least one electronic device located under, at a lower portion of, a display panel to effectively receive light while not being exposed in a front surface of the display device.

According to one or more aspects of the present disclosure, a display device may be provided that includes a light transmissive enhancement layer capable of increasing light transmittance even in an area of the common electrode where a hole is not present.

According to one or more aspects of the present disclosure, a display device may be provided that includes a structure of enabling a detection sensor located under, or at a lower portion of, a display panel to efficiently receive light while maintaining the characteristics of light emitting areas included in the display device.

According to one or more aspects of the present disclosure, a display device may be provided that includes a structure of enabling an infrared sensor located under, or at a lower portion of, a display panel to efficiently receive infrared light through an infrared transmissive layer, which is a type of light transmissive enhancement layer.

According to one or more aspects of the present disclosure, a display device may be provided that is capable of improving the efficiency of an electronic device by increasing the amount of light incident on the electronic device included in a display device without additional power consumption, and thereby enabling the display device to be driven at low power.

Effects or advantages according to aspects, examples, and embodiments of the present disclosure are not limited the foregoing description, and other effects or advantages will become apparent to those skilled in the art from the following description.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 illustrates an example display device according to aspects of the present disclosure;

FIG. 2 illustrates an example system configuration of the display device according to aspects of the present disclosure;

FIG. 3 illustrates an example configuration of a display panel according to aspects of the present disclosure;

FIG. 4 illustrates an example equivalent circuit of at least one subpixel included in the display device according to aspects of the present disclosure;

FIG. 5 illustrates example arrangements of subpixels disposed in first, second, and third display areas in the display panel according to aspects of the present disclosure;

FIG. 6 illustrates an example cross-sectional view of the first display area or the third display area in the display panel according to aspects of the present disclosure;

FIG. 7 illustrates an example situation of the first display area or the third display area allowing light to be transmitted in the display panel according to aspects of the present disclosure;

FIGS. 8 to 10 are example cross-sectional views of the first display area in the display panel according to aspects of the present disclosure;

FIG. 11 is an example plan view of the first display area in the display panel according to aspects of the present disclosure;

FIG. 12 are an example cross-sectional view of the first display area in the display panel according to aspects of the present disclosure;

FIG. 13 is an example plan view of the first display area in the display panel according to aspects of the present disclosure; and

FIG. 14 illustrates example light transmittances in the display panel according to wavelengths of light transmitted through the first display area in the display device according to aspects of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference will now be made in detail to example embodiments of the present disclosure, examples or aspects of which may be illustrated in the accompanying drawings. In the following description, the structures, implementations, methods, and operations described herein are not limited to the specific examples, aspects, and embodiments set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents. In the following description, where the detailed description of the relevant known function or configuration may unnecessarily obscure aspects of the present disclosure, a detailed description of such known function or configuration may be omitted. The shapes, sizes, ratios, angles, numbers, and the like, which are illustrated in the drawings to describe various example embodiments of the present disclosure, are merely given by way of example. Therefore, the present disclosure is not limited to the illustrations in the drawings. The terms such as “including,” “having,” “containing,” “constituting,” “make up of,” and “formed of” used herein are generally intended to allow other components to be added unless the terms are used with the term “only.” As used herein, singular forms are intended to include plural forms unless the context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise.

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to,” “contacts,” “overlaps with,” or the like a second element, it should be interpreted that, not only can the first element “be directly connected or coupled to,” “directly contact,” or “directly overlap with” the second element, but a third element can also be “interposed” between the first and second elements, or the first and second elements can “be connected or coupled to,” “contact,” “overlap with,” or the like each other via a fourth element. Here, the second element may be included in at least one of two or more elements that “are connected or coupled to,” “contact,” “overlap with,” or the like each other.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom,” “downward,” “upward,” “upper,” “lower,” and the like refer to an arbitrary frame of reference.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom,” “downward,” “upward,” “upper,” “lower,” and the like refer to an arbitrary frame of reference.

In addition, when any dimensions, relative sizes, and the like are mentioned, it should be considered that numerical values for an elements or features, or corresponding information (e.g., level, range, and the like) include a tolerance or error range that may be caused by various factors (e.g., process factors, internal or external impact, noise, and the like) even when a relevant description is not specified. Further, the term “may” fully encompasses all the meanings of the term “can.”

In the following description, various example aspects of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, aspects of the present disclosure are not limited to a scale, dimension, size, and thickness illustrated in the drawings.

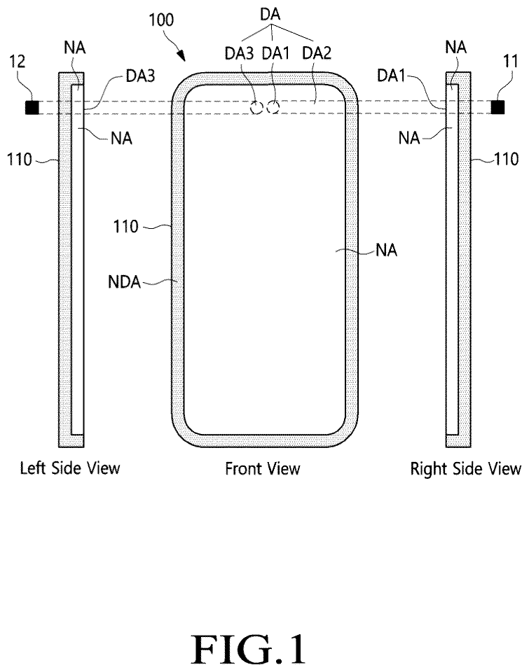

FIG. 1 illustrates an example display device 100 according to aspects of the present disclosure.

Referring to FIG. 1, in one or more example embodiments, the display device 100 may include a display panel 110 for displaying an image, and one or more electronic devices (11 and/or 12). Herein, an electronic device may be referred to as a light detector, a light receiver, or a light sensing device. An electronic device may include one or more of a camera, a camera lens, a sensor, a sensor for detecting images, or the like.

The display panel 110 may include a display area DA in which images can be displayed and a non-display area NDA in which an image is not displayed.

A plurality of subpixels may be disposed in the display area DA, and several types of signal lines for driving the plurality of subpixels may be disposed therein.

The non-display area NDA may be an area outside of the display area DA. Several types of signal lines may be disposed in the non-display area NDA, and several types of driving circuits may be connected thereto. At least a portion of the non-display area NDA may be bent to be invisible in front of the display device 100 or may be covered by a case or housing (not shown) of the display device 100. The non-display area NDA may be also referred to as a non-active area, bezel, or bezel area.

The display area DA may include a first display area DA1, a second display area DA2, and a third display area DA3.

An optical area may be included in the first display area DA1 and the third display area DA3, which allow light to be transmitted, and a normal area NA may correspond to, or be included in, the second display area DA2 not intended to allow light to be transmitted. A light transmittance in the optical area may be greater than a light transmittance in the normal area NA.

Therefore, a light transmittance in the first display area DA1 and the third display area DA3 may be greater than a light transmittance in the normal area NA.

Herein, the transmission, passing, or traveling of light through the optical area may mean that light enters the front surface of the display panel 110, passes through the display panel 110, and exits the back surface of the display panel 110.

Hereinafter, the normal area NA may also be referred to as the second display area DA2.

In one or more aspects, the one or more electronic devices (11 and/or 12) may be prepared as a separate device and thereafter included in the display device 100. For example, the one or more electronic devices (11 and/or 12) may be located under, or at a lower portion of, the display panel 110 (an opposite side to the viewing surface thereof).

Light can enter the front surface (the viewing surface) of the display panel 110, pass through the display panel 110, reach one or more electronic devices (11 and/or 12) located under, or at the lower portion of, the display panel 110 (the opposite side of the viewing surface). Light passing through the display panel 110 may include, for example, visible light, ultraviolet light, or the like.

The one or more electronic devices (11 and/or 12) may be devices capable of receiving or detecting light passing through the display panel 110 and perform a predefined function based on the received light. At least a portion of the first optical area DA1 may overlap with a first electronic device 11, and at least a portion of the third optical area DA3 may overlap with a second electronic device 12.

The first electronic device 11 can perform a predetermined operation using light of a first wavelength band among light transmitted through the first display area DA1. The second electronic device 12 can perform a predetermined operation using light of a second wavelength band different from the first wavelength band among light transmitted through the third display area DA3.

The first wavelength band may include at least one of a wavelength band of visible light, a wavelength band of infrared light, and a wavelength band of ultraviolet light. The second wavelength band may include at least one of a wavelength band of visible light, a wavelength band of infrared light, and a wavelength band of ultraviolet light, but may be different from the first wavelength band.

For example, the one or more electronic devices (11 and/or 12) may include one or more of the following: an image capture device such as a camera, an image sensor, and/or the like; or a sensor such as a proximity sensor, an illuminance sensor, and/or the like. For example, the sensor may be an infrared sensor capable of performing a predetermined operation using infrared light.

In one or more aspects, one or more display areas (DA1 and/or DA3) including corresponding one or more optical areas may be desired to include both an image display structure and a light transmissive structure. For example, since the one or more display areas (DA1 and/or DA3) including corresponding one or more optical areas are included in the display area DA, subpixels for displaying images may be desired to be disposed in the one or more display areas (DA1 and/or DA3). Further, to enable light to reach the one or more electronic devices (11 and/or 12), a light transmissive structure may be desirable to be formed in the one or more display areas (DA1 and/or DA3) including corresponding one or more optical areas.

It should be noted that even though the one or more electronic devices (11 and/or 12) are devices that need to receive light, the one or more electronic devices (11 and/or 12) may be located on the back of the display panel 110 (e.g., on an opposite side of the viewing surface thereof), and thereby, can receive light passing through the display panel 110. For example, the one or more electronic devices (11 and/or 12) may not be exposed in the front surface (viewing surface) of the display panel 110 or the display device 100. Accordingly, when a user views the front surface of the display device 100, the one or more electronic devices (11 and/or 12) may be invisible to the user.

For example, the first electronic device 11 may be a sensor such as a proximity sensor, an illuminance sensor, an infrared sensor, or the like, and the second electronic device 12 may be a camera, an image sensor, or the like. For example, the sensor may be an infrared sensor capable of detecting infrared light. In another example, the first electronic device 11 may be a camera, an image sensor, or the like, and the second electronic device 12 may be a sensor such as a proximity sensor, an illuminance sensor, an infrared sensor, or the like.

The display area DA may be an area where an image can be displayed. It should be noted here that the normal area NA may be an area where a light transmissive structure need not be formed, and the first display area DA1 and the third display area DA3 may be areas where a light transmissive structure needs to be formed.

Accordingly, the one or more display areas (DA1 and/or DA3) including corresponding one or more optical areas may have a transmittance greater than or equal to a predetermined level, i.e., a relatively high transmittance, and the normal area NA may have a transmittance less than the predetermined level or not have light transmittance.

For example, the one or more display areas (DA1 and/or DA3) including corresponding one or more optical areas may have a resolution, a subpixel arrangement structure, the number of subpixels per unit area, an electrode structure, a line structure, an electrode arrangement structure, a line arrangement structure, or/and the like different from that/those of the normal area NA.

The first display area DA1 and the third display area DA3 may have various shapes, such as a circle, an ellipse, a quadrangle, a hexagon, an octagon or the like. The first display area DA1 and the third display area DA3 may have the same or substantially or nearly the same shape, or different shapes. For example, a size of the first display area DA1 may be smaller than a size of the third display area DA3.

Herein, the display device 100 having a structure in which the first electronic device 11, for example, a sensor such as a proximity sensor, an illuminance sensor, an infrared sensor, or the like is located under, or at a lower portion of, the display panel 110 without being exposed to the outside may be referred to as a display to which under-display infrared radiation (UDIR) technology is applied.

Further, the display device 100 having a structure in which the second electronic device 2, for example, a camera is located under, or at a lower portion of, the display panel 110 without being exposed to the outside may be referred to as a display to which the under-display camera (UDC) technology is applied.

According to these structures, the display device 100 can provide an advantage of preventing a size of the display area DA from being reduced because a notch or a camera hole for exposing a sensor or camera need not be formed in the display panel 110. Indeed, the display device 100 can provide advantages of reducing a size of a bezel area, and improving the degree of freedom in design because such limitations to the design are removed.

Although the one or more electronic devices (11 and/or 12) are located on the back of (e.g., under, or at a lower portion of) the display panel 110 of the display device 100 (e.g., hidden or not to be exposed to the outside), the one or more electronic devices (11 and/or 12) are needed to normally receive or detect light passing through the display panel 110 and perform a predefined function based on the received light.

Further, in the display device 100, although one or more electronic devices (11 and/or 12) are located on the back of (e.g., under, or at a lower portion of) the display panel 110, it is necessary for image display to be normally performed in the one or more display areas (DA1 and/or DA3) including corresponding one or more optical areas and overlapping with the one or more electronic devices (11 and/or 12).

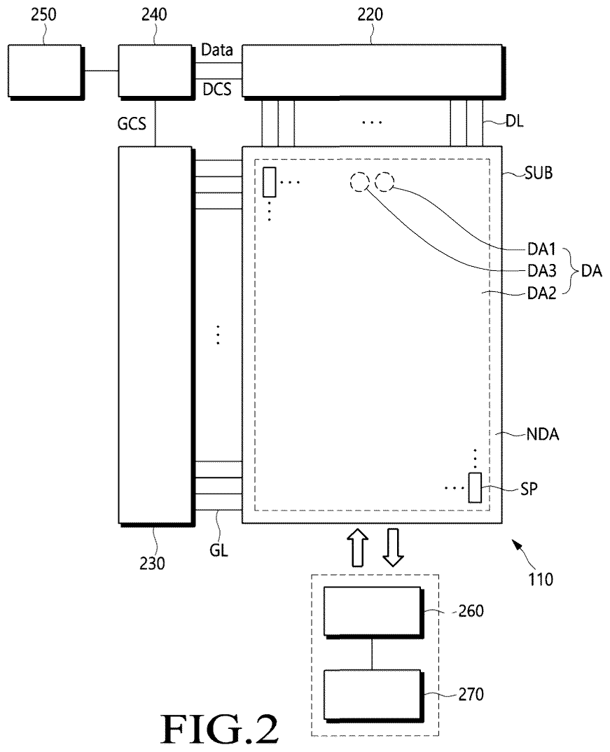

FIG. 2 illustrates an example system configuration of the display device 100 according to aspects of the present disclosure.

Referring to FIG. 2, in one or more example embodiments, the display device 100 may include the display panel 110 and at least one display driving circuit as components for displaying one or more images.

The at least one display driving circuit may be a circuit for driving the display panel 110, and include a data driving circuit 220, a gate driving circuit 230, a display controller 240, and other circuit components.

The display panel 110 may include the display area DA in which images can be displayed and the non-display area NDA in which an image is not displayed.

The display panel 110 may include a substrate SUB and a plurality of subpixels SP disposed on the substrate SUB. The display panel 110 may further include several types of signal lines to drive the plurality of subpixels SP.

The structure of each of the plurality of subpixels SP may be differently configured or designed according to types of the display device 100. For example, when the display device 100 is a self-emissive display device including self-emissive subpixels SP, each subpixel SP may include a self-emissive light emitting element, one or more transistors, and one or more capacitors.

In one or more aspects, several types of signal lines disposed in the display device 100 may include, for example, a plurality of data lines DL for delivering data signals (which may be referred to as data voltages or image signals), a plurality of gate lines GL for delivering gate signals (which may be referred to as scan signals), and the like.

The plurality of data lines DL and the plurality of gate lines GL may intersect each other.

The data driving circuit 220 may be a circuit for driving the plurality of data lines DL, and can supply data signals to the plurality of data lines DL. The gate driving circuit 230 may be a circuit for driving the plurality of gate lines GL, and can supply gate signals to the plurality of gate lines GL.

The display controller 240 may be a device for controlling the data driving circuit 220 and the gate driving circuit 230, and can control driving times for the plurality of data lines DL and driving times for the plurality of gate lines GL.

The display controller 240 can supply a data driving control signal DCS to the data driving circuit 220 to control the data driving circuit 220, and supply a gate driving control signal GCS to the gate driving circuit 230 to control the gate driving circuit 230.

The display controller 240 can receive input image data from a host system 250 and supply image data based on the input image data to the data driving circuit 220.

The data driving circuit 220 can receive digital image data from the display controller 240, convert the received image data into analog data signals, and output the resulting analog data signals to the plurality of data lines DL.

The gate driving circuit 230 can receive a first gate voltage corresponding to a turn-on level voltage and a second gate voltage corresponding to a turn-off level voltage along with various gate driving control signals GCS, generate gate signals, and supply the generated gate signals to the plurality of gate lines GL.

In one or more aspects, the data driving circuit 220 may be disposed in, and/or electrically connected to, but not limited to, only one side or edge (e.g., an upper portion or a lower portion) of the display panel 110. In one or more aspects, the data driving circuit 220 may be located in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

In one or more aspects, the gate driving circuit 230 may be located in, and/or electrically connected to, but not limited to, one side or edge (e.g., a left portion or a right portion) of the display panel 110. In one or more aspects, the gate driving circuit 230 may be located in, and/or electrically connected to, but not limited to, two sides or edges (e.g., a left portion and a right portion) of the panel 110 or at least two of four sides or edges (e.g., an upper portion, a lower portion, the left portion, and the right portion) of the panel 110 according to driving schemes, panel design schemes, or the like.

The display controller 240 may be implemented in a separate component from the data driving circuit 220, or integrated with the data driving circuit 220, so that the display controller 240 and the data driving circuit 220 can be implemented in a single integrated circuit.

In one or more aspects, to further provide a touch sensing function as well as an image display function, the display device 100 may include at least one touch sensor, and a touch sensing circuit capable of detecting whether a touch event occurs by a touch object such as a finger, a pen, or the like, or of detecting a corresponding touch position, by sensing the touch sensor.

The touch sensing circuit may include a touch driving circuit 260 capable of generating and providing touch sensing data by driving and sensing the touch sensor, a touch controller 270 capable of detecting the occurrence of a touch event or detecting a touch position (or touch coordinates) using the touch sensing data, and one or more other components.

The touch sensor may be implemented in the form of a touch panel outside of the display panel 110 or be integrated inside of the display panel 110.

In the example where the touch sensor is integrated inside of the display panel 110, the touch sensor may be formed on the substrate SUB together with signal lines and electrodes related to display driving during a process of manufacturing the display panel 110.

The touch driving circuit 260 can supply a touch driving signal to at least one of a plurality of touch electrodes, and sense at least one of the plurality of touch electrodes to generate touch sensing data.

In one or more aspects, the touch driving circuit 260 and the touch controller 270, which are included in the touch sensing circuit, may be implemented in separate devices or in one device.

In the display panel 110, the display area DA may include the first display area DA1, the second display area DA2, and the third display area DA3, and the first display area DA1 and the third display area DA3 may include an optical area, and the second display area DA2 may include the normal area NA. All of the first display area DA1, the second display area DA2, and the third display area DA3 may be areas allowing images to be displayed. It should be noted that the second display area DA2 may be an area where a light transmissive structure need not be formed, and the first display area DA1 and the third display area DA3 may be areas where a light transmissive structure needs to be formed.

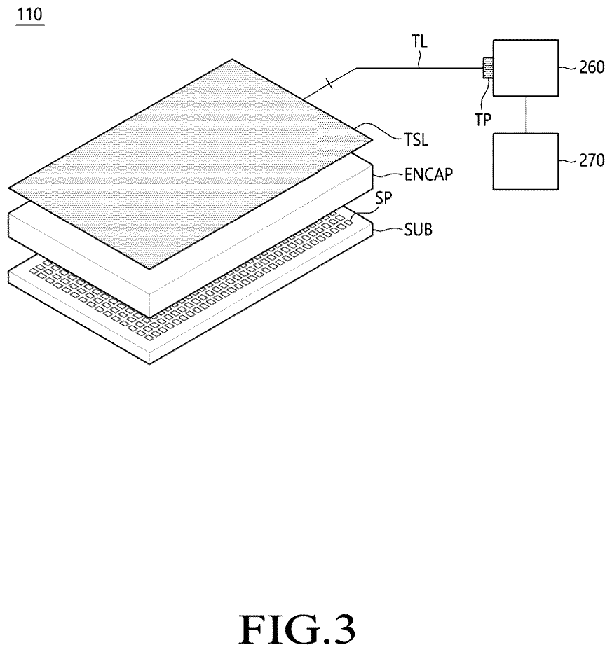

FIG. 3 illustrates an example configuration of the display panel 110 according to aspects of the present disclosure.

Referring to FIG. 3, a plurality of subpixels SP may be disposed in the display area DA of the display panel 110.

Referring to FIG. 3, in one or more example embodiments, to sense a touch of a user, the display device 100 may include a touch sensor layer TSL including a plurality of sensor electrodes, a touch driving circuit 260 configured to sense the plurality of sensor electrodes, and a touch controller 270 configured to determine whether a touch is applied or a location of the touch (e.g., touch coordinates) based on the sensing result (e.g., touch sensing data) of the touch driving circuit 260.

The touch sensor layer TSL may be embedded in the display panel 110. For example, the touch sensor layer TSL may be disposed on an encapsulation layer ENCAP of the display panel 110.

The encapsulation layer ENCAP may be in the form of one layer or multilayer. For example, when the encapsulation layer ENCAP is in the form of a multilayer, the encapsulation layer ENCAP may include one or more inorganic encapsulation layers and one or more organic encapsulation layers. For example, the encapsulation layer ENCAP may include a first inorganic encapsulation layer, an organic encapsulation layer, and a second inorganic encapsulation layer. The organic encapsulation layer may be interposed between the first inorganic encapsulation layer and the second inorganic encapsulation layer.

The first inorganic encapsulation layer may include an inorganic insulating material capable of being deposited at a low temperature, such as silicon nitride (SiNx), silicon oxide (SiOx), silicon oxynitride (SiON), aluminum oxide (Al2O3), or the like. Accordingly, since the first inorganic encapsulation layer is deposited in a low temperature atmosphere, an emission layer (e.g., an organic emission layer) that is vulnerable to high temperatures can be prevented from being damaged during the process of forming the first inorganic encapsulation layer.

The organic encapsulation layer may be formed such that the organic encapsulation layer has an area smaller than the first inorganic encapsulation layer and exposes both ends of the first inorganic encapsulation layer. The organic encapsulation layer can act as a buffer to relieve stress between layers due to bending of the display device, and can enhance flattening performance. The organic encapsulation layer may include an organic insulating material, such as, an acrylic resin, an epoxy resin, a polyimide, polyethylene, silicon oxycarbon (SiOC), or the like.

The second inorganic encapsulation layer may be disposed on the organic encapsulation layer such that the second inorganic encapsulation layer covers respective upper surfaces and side surfaces of the organic encapsulation layer and the first inorganic encapsulation layer. Accordingly, the second inorganic encapsulation layer can minimize or block external moisture or oxygen from penetrating into the first inorganic encapsulation layer and the organic encapsulation layer. The second inorganic encapsulation layer may include, for example, an inorganic insulating material, such as, for example, silicon nitride (SiNx), silicon oxide (SiOx), silicon oxynitride (SiON), aluminum oxide (Al2O3) or the like.

The display panel 110 may further include a plurality of touch pads TP to which the touch driving circuit 260 is electrically connected, and a plurality of touch routing lines TL for electrically connecting a plurality of sensor electrodes included in the touch sensor layer TSL to the plurality of touch pads TP to which the touch driving circuit 260 is connected.

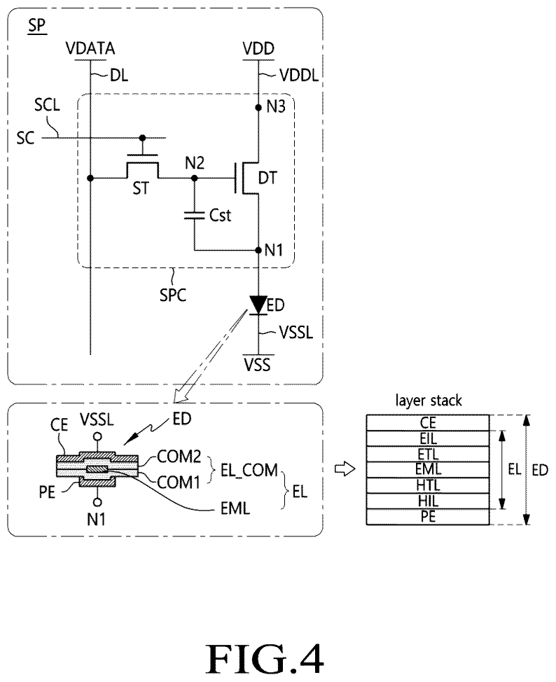

FIG. 4 illustrates an example equivalent circuit SPC of at least one subpixel SP included in the display device 100 according to aspects of the present disclosure.

Referring to FIG. 4, in one or more example embodiments, a subpixel circuit SPC included in each subpixel SP may include a driving transistor DT for driving a light emitting element ED, a scan transistor ST for transferring a data voltage VDATA to the driving transistor DT, a storage capacitor Cst for maintaining a voltage at an approximate constant level during one frame, and the like.

The driving transistor DT may include a first node N1, a second node N2, and a third node N3.

The first node N1 may be a node connected to the light emitting element ED. The second node N2 may be a node connected to the scan transistor ST. The third node N3 may be a node connected to a driving voltage line VDDL.

The first node N1 may be electrically connected to a pixel electrode PE of the light emitting element ED. A data voltage VDATA may be applied to the second node N2. A driving voltage VDD may be applied to the third node N3.

The first node N1 may be a source node or a drain node of the driving transistor DT, the second node N2 may be a gate node of the driving transistor DT, and the third node N3 may be the drain node or the source node of the driving transistor DT. Hereinafter, for convenience of explanation, discussions are provided based on examples where the first node N1 is the source node of the driving transistor DT, the second node N2 is the gate node of the driving transistor DT, and the third node N3 is the drain node of the driving transistor DT.

The light emitting element ED may include the pixel electrode PE, an intermediate layer EL, and a common electrode CE.

The pixel electrode PE may be an electrode disposed for each subpixel SP. For example, the pixel electrode PE may be electrically connected directly or indirectly (via another transistor) to the first node N1 of the driving transistor DT of each subpixel SP.

The common electrode CE may be an electrode disposed in common in all or some of a plurality of subpixels SP. For example, a base voltage VSS, which is a type of common driving voltage, may be applied to the common electrode CE through the base voltage line VSSL.

For example, the pixel electrode PE may be an anode electrode, and the common electrode CE may be a cathode electrode. In another example, the pixel electrode PE may be a cathode electrode, and the common electrode CE may be an anode electrode. Hereinafter, for convenience of explanation, discussions are provided based on examples where the pixel electrode PE is an anode electrode, and the common electrode CE is a cathode electrode.

The intermediate layer EL may include an emission layer EML and a common intermediate layer EL_COM.

The emission layer EML may be disposed in a light emitting area of each of a plurality of subpixels SP.

The common intermediate layer EL_COM may be disposed commonly across all or some of a plurality of subpixels SP. The common intermediate layer EL_COM may be disposed commonly across a plurality of light emitting areas and a non-light emitting area.

The common intermediate layer EL_COM may include a first common intermediate layer COM1 and a second common intermediate layer COM2. The first common intermediate layer COM1 may be disposed between the pixel electrode PE and the emission layer EML and may include at least one layer (e.g., an organic layer). The second common intermediate layer COM2 may be disposed between the emission layer EML and the common electrode CE and may include at least one layer (e.g., an organic layer). For example, the first common intermediate layer COM1 may include a hole injection layer HIL and a hole transport layer HTL. The second common intermediate layer COM2 may include an electron transport layer ETL and an electron injection layer EIL.

The hole injection layer can inject holes from the pixel electrode PE to the hole transport layer, the hole transport layer can transport holes to the emission layer EML, the electron injection layer can inject electrons from the common electrode CE to the electron transport layer, and the electron transport layer can transport electrons to the emission layer EML. Each light emitting element ED may be configured by overlapping of a pixel electrode PE, an emission layer EML in an intermediate layer EL, and a common electrode CE. A respective light emitting area may be formed by each light emitting element ED. For example, the light emitting area may be defined as an area where the pixel electrode PE, the emission layer EML of the intermediate layer EL, and the common electrode CE overlap with each other.

For example, the light emitting element ED may be an organic light emitting diode (OLED), an inorganic light emitting diode, a quantum dot light emitting element, or the like. In an example where the organic light emitting diode is used as the light emitting element ED, the intermediate layer EL thereof may be in the form of an organic layer including an organic material.

The scan transistor ST can be turned on or turned off by a scan signal SC, which is a type of gate signal, applied through a scan signal line SCL, which is a type of gate line GL, and may be electrically connected between the second node N2 of the driving transistor DT and a data line DL.

The storage capacitor Cst may be electrically connected between the first node N1 and the second node N2 of the driving transistor DT.

Since circuit elements (e.g., a light emitting element ED such as an organic light emitting diode (OLED) including an organic material) in each subpixel SP are vulnerable to external moisture or oxygen, an encapsulation layer may be disposed at the display panel 110 to prevent the external moisture or oxygen from penetrating into the circuit elements (e.g., the light emitting element ED). The encapsulation layer may be disposed to cover the light emitting element ED.

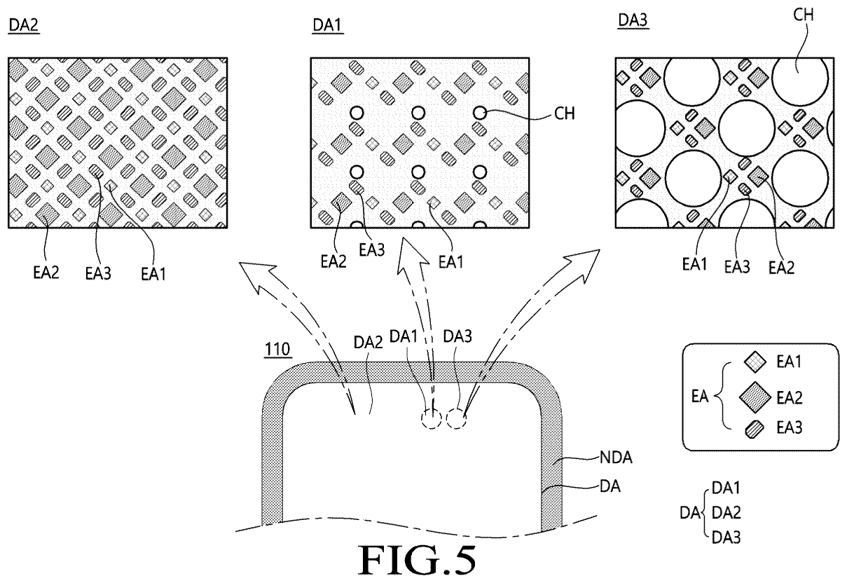

FIG. 5 illustrates an example cross-sectional view of the first display area DA1, the second display area DA2, and the third display area DA3 in the display panel 110 according to aspects of the present disclosure.

Referring to FIG. 5, in one or more example embodiments, the display panel 110 may include the display area DA where an image is displayed and the non-display area NDA where an image is not displayed.

Referring to FIG. 5, the display area DA may include the first display area DA1, the third display area DA3, and the second display area DA2 outside of the first display area DA1 and the third display area DA3.

Each of the first display area DA1 and the third display area DA3 may have a light transmissive structure. However, the first display area DA1 and the third display area DA3 may have different structural characteristics. For example, a light transmittance of the first display area DA1 may be less than a light transmittance of the third display area DA3. For example, a resolution of the first display area DA1 may be greater than a resolution of the third display area DA3. For example, the number of subpixels per unit area of the first display area DA1 may be greater than the number of subpixels per unit area of the third display area DA3. For example, a subpixel size of the first display area DA1 may be greater than a subpixel size of the third display area DA3.

The first electronic device 11 overlapped with at least a portion of the first display area DA1 can perform a predetermined operation using light of a first wavelength band among light transmitted through the first display area DA1. The second electronic device 12 being overlapped with at least a portion of the third display area DA3 can perform a predetermined operation using light of a second wavelength band different from the first wavelength band among light transmitted through the third display area DA3.

The first wavelength band may include at least one of a wavelength band of visible light, a wavelength band of infrared light, and a wavelength band of ultraviolet light. The second wavelength band may include at least one of a wavelength band of visible light, a wavelength band of infrared light, and a wavelength band of ultraviolet light, but may be different from the first wavelength band.

For example, the first electronic device 11 may be a sensor, and the second electronic device 12 may be a camera.

For example, the first electronic device 11 can perform a predetermined operation using light of an infrared wavelength band corresponding to the first wavelength band among light transmitted through the first display area DA1. The second electronic device 12 can perform a predetermined operation using light of a visible light wavelength band corresponding to the second wavelength band among light transmitted through the third display area DA3.

The display area DA may include a plurality of light emitting areas EA and a non-light emitting area. Since the first display area DA1, the second display area DA2, and the third display area DA3 are areas included in the display area DA, each of the first display area DA1, the second display area DA2, and the third display area DA3 may include a plurality of light emitting areas EA.

A plurality of light emitting areas EA disposed in the display area DA may include at least one first color light emitting area EA1 configured to emit light of a first color, at least one second color light emitting area EA2 configured to emit light of a second color, and at least one third color light emitting area EA3 configured to emit light of a third color. At least one of the first color light emitting area EA1, the second color light emitting area EA2, and the third color light emitting area EA3 may have an area different from the one or more remaining light emitting areas. The first color, the second color, and the third color may be different colors from each other, and may be various colors. For example, the first color, second color, and third color may be or include red, green, and blue, respectively.

Referring to FIG. 5, each of the first display area DA1 and the third display area DA3 may include at least one common electrode hole CH formed in a common electrode. Each common electrode hole CH may be disposed between two adjacent light emitting areas EA. For example, common electrode holes CH may be formed to increase light transmittance in the first display area DA1 and the third display area DA3.

For example, a shape of the common electrode holes CH may have various shapes such as a circle, an oval, a square, a hexagon, or an octagon.

For example, common electrode holes CH may be disposed regularly or irregularly.

In the example where the common electrode holes CH are regularly disposed, a duration between a first common electrode hole CH and a second common electrode hole CH adjacent to the first common electrode hole CH may be the same, or substantially the same, as a duration between the second common electrode hole CH and a third common electrode hole CH adjacent to the second common electrode hole CH.

In the example where the common electrode holes CH are irregularly disposed, a duration between the adjacent first and second common electrode holes CH may be different from a duration between the adjacent second and third common electrode holes CH.

To pattern the common electrode CE, a metal patterning layer may be disposed on the common electrode holes CH.

In an example where the common electrode CE is a cathode, a common electrode patterning material included in the metal patterning layer may be a cathode patterning material CPM. For example, the metal patterning layer may include a fluorine-based compound or an organic material.

In the first display area DA1 and the third display area DA3, areas where common electrode holes CH are formed may have higher light transmittance than an area where a common electrode hole CH is not formed.

However, when too many common electrode holes CH are formed, the probability of causing damage to light emitting elements under high temperature and high humidity conditions may increase, and therefore, the common electrode holes CH may not be desired to be formed over a large area.

To address this issue, the inventors of the present disclosure have designed the display device 100 having a structure including a light transmissive enhancement layer in the first display area DA1 and/or the third display area DA3 to increase light transmittance even in an area other than the common electrode holes CH of the first display area DA1 and/or the third display area DA3.

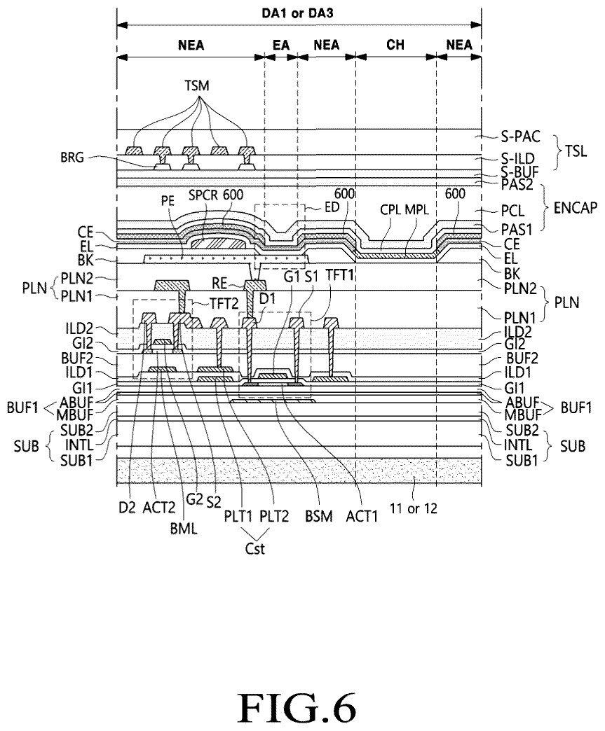

Hereinafter, an example configuration of such a light transmissive enhancement layer according to example embodiments of the present disclosure will be described in more detail with reference to FIGS. 6 to 13.

FIG. 6 illustrates an example cross-sectional view of the first display area DA1 or the third display area DA3 in the display panel 110 according to aspects of the present disclosure.

Referring to FIG. 6, in one or more example embodiments, the first display area DA1 and the third display area DA3 may include a plurality of light emitting areas EA, a non-light emitting area NEA, and common electrode holes CH.

The light emitting areas EA may be areas including light emitting elements ED in which a common electrode hole CH is not formed.

The non-light emitting area NEA may be an area where the light emitting elements ED and the common electrode holes CH are not formed.

Areas where the common electrode holes CH are formed may be areas where a light emitting element ED is not formed and holes are formed in a common electrode CE.

The areas where the common electrode holes CH are formed may have light transmittance greater than an area where a common electrode hole CH is not formed.

One common electrode hole CH may disposed between two adjacent light emitting areas EA, and in this configuration, a shape of the common electrode hole CH may have various shapes such as a circle, an oval, a square, a hexagon, or an octagon.

The display panel 110 may include a transistor part, a light emitting element part, an encapsulation part, and a touch sensor.

The transistor part may include a substrate SUB, a first buffer layer BUF1 disposed on the substrate SUB, and several transistors (TFT1, TFT2, etc.) disposed on the first buffer layer BUF, a storage capacitor Cst, and several electrodes or signal lines.

The substrate SUB may include a first substrate SUB1 and a second substrate SUB2, and may include a substrate intermediate layer INTL between the first substrate SUB1 and the second substrate SUB2. For example, the substrate intermediate layer INTL may be an inorganic layer and can block moisture penetration.

A lower shield metal BSM may be disposed on the substrate SUB. The lower shield metal BSM may be located under a first active layer ACT1 of a first transistor TFT1.

The first buffer layer BUF1 may be in the form of a single layer or a multilayer. In the example where the first buffer layer BUF1 is in the form of a multilayer, the first buffer layer BUF1 may include a multi-buffer layer MBUF and an active buffer layer ABUF.

Several transistors (TFT1, TFT2, etc.), the storage capacitor Cst, and several electrodes or signal lines may be disposed on the first buffer layer BUF1.

For example, the transistors (TFT1, TFT2, etc.) disposed on the first buffer layer BUF1 may include the same material and may be located in the same layers. In another example, as illustrated in FIG. 6, among the transistors (TFT1, TFT2, etc.), first and second transistors (TFT1 and TFT2) may include different materials and may be located in different layers.

The first transistor TFT1 may include a first active layer ACT1, a first gate electrode G1, a first source electrode S1, and a first drain electrode D1. The second transistor TFT2 may include a second active layer ACT2, a second gate electrode G2, a second source electrode S2, and a second drain electrode D2.

The second active layer ACT2 of the second transistor TFT2 may be located higher than the first active layer ACT1 of the first transistor TFT in the cress-sectional view.

The first active layer ACT1 of the first transistor TFT1 and the second active layer ACT2 of the second transistor TFT2 may include different semiconductor materials. For example, the first active layer ACT1 of the first transistor TFT1 may include a different semiconductor material from the second active layer ACT2 of the second transistor TFT2. For example, the first active layer ACT1 of the first transistor TFT1 may include a silicon-based semiconductor material. For example, the silicon-based semiconductor material may include low-temperature polycrystalline silicon (LTPS) or the like. For example, the second active layer ACT2 of the second transistor TFT2 may include an oxide semiconductor material. For example, the oxide semiconductor material may include indium gallium zinc oxide (IGZO), indium gallium zinc tin oxide (IGZTO), zinc oxide (ZnO), cadmium oxide (CdO), indium oxide (InO), zinc tin oxide (ZTO), zinc indium tin oxide (ZITO), and/or the like.

The first buffer layer BUF1 may be disposed under the first active layer ACT1 of the first transistor TFT1, and a second buffer layer BUF2 may be disposed under the second active layer ACT2 of the second transistor TFT2.

For example, the first active layer ACT1 of the first transistor TFT1 may be located on the first buffer layer BUF1, and the second active layer ACT2 of the second transistor TFT2 may be located on the second buffer layer BUF2. For example, the second buffer layer BUF2 may be located higher than the first buffer layer BUF1 in the cress-sectional view.

The first active layer ACT1 of the first transistor TFT1 may be disposed on the first buffer layer BUF1, and a first gate insulating layer GI1 may be disposed on the first active layer ACT1 of the first transistor TFT1. The first gate electrode G1 of the first transistor TFT1 may be disposed on the first gate insulating layer GI1, and a first interlayer insulating layer ILD1 may be disposed on the first gate electrode G1 of the first transistor TFT1.

The first active layer ACT1 of the first transistor TFT1 may include a first channel region overlapping with the first gate electrode G1, a first source connection region located on one side of the first channel region, and a first drain connection region located on the other side of the channel region.

The second buffer layer BUF2 may be disposed on the first interlayer insulating layer ILD1.

The second active layer ACT2 of the second transistor TFT2 may be disposed on the second buffer layer BUF2, and a second gate insulating layer GI2 may be disposed on the second active layer ACT2. The second gate electrode G2 of the second transistor TFT2 may be disposed on the second gate insulating layer GI2, and a second interlayer insulating layer ILD2 may be disposed on the second gate electrode G2.

The second active layer ACT2 of the second transistor TFT2 may include a second channel region overlapping with the second gate electrode G2, a second source connection region located on one side of the second channel region, and a second drain connection region located on the other side of the channel region.

The first source electrode S1 and the first drain electrode D1 of the first transistor TFT1 may be disposed on the second interlayer insulating layer ILD2. The second source electrode S2 and the second drain electrode D2 of the second transistor TFT2 may be disposed on the second interlayer insulating layer ILD2.

The first source electrode S1 and the first drain electrode D1 of the first transistor TFT1 may be connected to the first source connection region and the first drain connection region of the first active layer ACT1, respectively, through holes of the second interlayer insulating layer ILD2, the second gate insulating layer GI2, the second buffer layer BUF2, the first interlayer insulating layer ILD1, and the first gate insulating layer GI1.

The second source electrode S2 and the second drain electrode D21 of the second transistor TFT2 may be connected to the second source connection region and the second drain connection region of the second active layer ACT2, respectively, through holes of the second interlayer insulating layer ILD2 and the second gate insulating layer GI2.

The storage capacitor Cst may include a first capacitor electrode PLT1 and a second capacitor electrode PLT2.

The first capacitor electrode PLT1 may be electrically connected to the second gate electrode G2 of the second transistor TFT2, and the second capacitor electrode PLT2 may be electrically connected to the second source electrode S2 of the second transistor TFT2.

A lower metal BML may be disposed under the second active layer ACT2 of the second transistor TFT2. The lower metal BML may be overlapped with all or a portion of the second active layer ACT2.

For example, the lower metal BML may be electrically connected to the second gate electrode G2. In another example, the lower metal BML may serve as a light shield for blocking light passing through one or more layers under the lower metal BML. For example, the lower metal BML may be electrically connected to the second source electrode S2.

For example, the first transistor TFT1 may be a driving transistor for driving a light emitting element ED, and the second transistor TFT2 may be a scan transistor or an emission control transistor. However, aspects of the present disclosure are not limited thereto. For example, as illustrated in FIG. 6, the first transistor TFT1 may be a scan transistor or an emission control transistor, and the second transistor TFT2 may be a driving transistor for driving the light emitting element ED. For example, the emission control transistor may be a transistor for controlling emission of the light emitting element by controlling a connection between the driving transistor and the light emitting element according to an emission control signal.

The display panel 110 may include a planarization layer PLN disposed on the first transistor TFT1 and the second transistor TFT2.

For example, the planarization layer PLN may include a first planarization layer PLN1. The first planarization layer PLN1 may be disposed on the first source electrode S1 and the first drain electrode D2 of the first transistor TFT1 and the second source electrode S2 and the second drain electrode D2 of the second transistor TFT2.

A relay electrode RE may be disposed on the first planarization layer PLN1. The relay electrode RE may be an electrode for interconnecting an electrical connection between the source electrode or the drain electrode of the transistor and a pixel electrode PE of the light emitting element ED. For example, the relay electrode RE may be electrically connected to the first drain electrode D1 or the first source electrode S1 of the first transistor TFT1 through a hole of the first planarization layer PLN1. In another example, the relay electrode RE may be electrically connected to the second source electrode S2 or the second drain electrode D2 of the second transistor TFT2 through a hole of the first planarization layer PLN1.

The planarization layer PLN disposed on the display panel 110 may further include a second planarization layer PLN2 on the first planarization layer PLN1. For example, the second planarization layer PLN2 may be disposed such that the second planarization layer PLN2 covers the relay electrode RE located on the first planarization layer PLN1.

Referring to FIG. 6, the light emitting element part may be located on the second planarization layer PNL2, and include the pixel electrode PE, an intermediate layer EL, and a common electrode CE for forming the light emitting element ED. The intermediate layer EL may include an emission layer.

The light emitting element ED may be configured by an area where the pixel electrode PE, the intermediate layer EL, and the common electrode CE overlap with each other.

The pixel electrode PE may be disposed on the second planarization layer PLN2. The pixel electrode PE may be connected to the relay electrode RE through a hole of the second planarization layer PLN2.

A bank BK may be disposed on the pixel electrode PE.

The bank BK may include an opening, and a portion of the pixel electrode PE may be exposed through the opening of the bank. For example, the opening disposed in the bank BK may overlap with a portion of the pixel electrode PE.

The intermediate layer EL may be disposed on the bank BK. The intermediate layer EL may contact the portion of the pixel electrode PE through the opening of the bank.

The intermediate layer EL may include an emission layer.

At least one spacer SPCR may be disposed between the intermediate layer EL and the bank BK. The spacer SPCR can minimize damage to the display device 100 due to external impact by buffering an empty space on the substrate SUB. The spacer SPCR may include the same material as the bank BK, and be disposed simultaneously with the bank BK.

The common electrode CE may be disposed on the intermediate layer EL. The common electrode CE may include at least one common electrode hole CH. The common electrode hole CH formed on the common electrode CE may be disposed in the first display area DA1 and the third display area DA3. One common electrode hole CH may be disposed between two adjacent light emitting areas EA.

A capping layer CPL may be disposed on the light emitting element ED to improve light extraction and protect the light emitting element ED. The capping layer CPL may include an organic material and have a specific refractive index. Thereby, the capping layer CPL can cause light to be focused and improve light extraction.

The capping layer CPL can also increase a reflectance at a boundary between the capping layer CPL and the outside by controlling a difference in refractive indexes with the outside.

The capping layer CPL may be disposed in all, or at least respective portions, of the non-light emitting area NEA, the light emitting areas EA, and areas where common electrode holes CH are disposed.

Referring to FIG. 6, the encapsulation part including an encapsulation layer ENCAP may be disposed on the capping layer CPL.

The encapsulation layer ENCAP may be a layer for preventing moisture or oxygen from penetrating into the light emitting element ED. For example, the encapsulation layer ENCAP may prevent moisture or oxygen from penetrating into the intermediate layer EL that may include an organic layer. For example, the encapsulation layer ENCAP may be in the form of a single layer or a multilayer.

The encapsulation layer ENCAP may include a first encapsulation layer PAS1, a second encapsulation layer PCL, and a third encapsulation layer PAS2. For example, the first encapsulation layer PAS1 and the third encapsulation layer PAS2 may be inorganic layers, and the second encapsulation layer PCL may be an organic layer. Since the second encapsulation layer PCL includes an organic layer, the second encapsulation layer PCL can also serve as a planarization layer. In one or more aspects, the display panel 110 may include a touch sensor layer TSL disposed on the encapsulation layer ENCAP.

The touch sensor layer TSL may include touch sensor metals TSM and bridge metals BRG, and may further include insulating layers such as a sensor buffer layer S-BUF, a sensor interlayer insulating layer S-ILD, and a sensor protection layer S-PAC. For example, the sensor interlayer insulating layer S-ILD may include one or more insulating layers.

The sensor buffer layer S-BUF may be disposed on the encapsulation layer ENCAP. The bridge metals BRG may be disposed on the sensor buffer layer S-BUF, and the sensor interlayer insulation layer S-ILD may be disposed on the bridge metals BRG. In one or more aspects, the sensor buffer layer S-BUF may be omitted.

The touch sensor metals TSM may be disposed on the sensor interlayer insulating layer S-ILD. A respective portion of the touch sensor metals TSM may be connected to a corresponding bridge metal BRG through a hole of the sensor interlayer insulating layer S-ILD.

The touch sensor metals TSM and the bridge metals BRG may be disposed in the non-light emitting area NEA within the first display area DA1 and the third display area DA3. The touch sensor metals TSM and the bridge metals BRG may not be disposed in areas where common electrode holes CH are disposed in the first display area DA1 and the third display area DA3. The touch sensor metals TSM and the bridge metals BRG may be disposed not to overlap with light emitting areas EA.

A plurality of touch sensor metals TSM may be included in one touch electrode (or one touch electrode line), and may form a mesh in which the plurality of touch sensor metals TSM are electrically connected to each other. One or more of the touch sensor metals TSM and one or more of the remaining one or more touch sensor metals TSM may be electrically connected through one or more bridge metals BRG to form one touch electrode (or one touch electrode line).

The sensor protection layer S-PAC may be disposed such that it covers the touch sensor metals TSM and the bridge metals BRG.

At least one of the touch sensor metals TSM (or at least a respective portion of at least one touch sensor metal TSM) located on the encapsulation layer ENCAP in the display area DA may extend along an outer inclined surface of the encapsulation layer ENCAP, and be electrically connected to a pad located further outwardly than the outer inclined surface of the encapsulation layer ENCAP. For example, the pad may be disposed in the non-display area NDA, and may be a metal pattern to which a touch driving circuit is electrically connected.

For example, an opening of the bank BK may be disposed in an area where a common electrode hole CH is disposed. For example, the bank BK may have an opening overlapping with an area where a common electrode hole CH is disposed.

The cross-sectional structures of a portion of the non-light emitting area NEA except for area where common electrode holes CH are disposed and light emitting areas EA in the first display area DA1 and the third display area DA3 may be substantially equal to corresponding cross-sectional structure of the second display area DA2.

At least a respective portion of the first display area DA1 and the third display area DA3 may overlap with a corresponding electronic device. For example, at least a portion of the first optical area DA1 may overlap with the first electronic device 11, and at least a portion of the third optical area DA3 may overlap with the second electronic device 12.

The first electronic device 11 and the second electronic device 12 may be electronic devices capable of receiving light of a specific wavelength and performing a predetermined operation. For example, the first electronic device 11 may be an electronic device capable of performing a predetermined operation using light of a first wavelength, and the second electronic device 12 may be an electronic device capable of performing a predetermined operation using light of a second wavelength different from the light of the first wavelength.

For example, the first wavelength may include one or more of a wavelength band of visible light, a wavelength band of infrared light, a wavelength band of ultraviolet light, and the like. The second wavelength may include one or more of a wavelength band of visible light, a wavelength band of infrared light, a wavelength band of ultraviolet light, and the like, but may be different from the first wavelength.

To enable the first electronic device 11 and the second electronic device 12 to receive a greater amount of light, each of the first display area DA1 and the third display area DA3 may include at least one common electrode hole CH disposed in the common electrode. Therefore, areas where the common electrode holes CH are formed may have light transmittance greater than an area where a common electrode hole CH is not formed.

To pattern the common electrode CE, a metal patterning layer MPL may be disposed in common electrode holes CH. After the metal patterning layer MPL is disposed, the common electrode CE may be disposed.

The metal patterning layer MPL may include a common electrode patterning material. For example, when the common electrode CE is a cathode, the common electrode patterning material included in the metal patterning layer MPL may be a cathode patterning material CPM.

The metal patterning layer MPL may have various shapes, such as a circle, an oval, and an octagon.

However, the common electrode hole CH and the metal patterning layer MPL disposed on the common electrode hole CH may be desired not to be disposed excessively due to a reliability issue. Therefore, to address this issue, in one or more aspects, a light transmissive enhancement layer 600 may be disposed between the bank BK and the encapsulation layer ENCAP in the display panel 110. Through this configuration, light transmittance can be increased, and thereby, the first electronic device 11 and/or the second electronic device 12 in the first display area DA1 and/or the third display area DA3 can receive or detect a greater amount of light.

For example, the light transmissive enhancement layer 600 may be disposed in an area excluding light emitting areas EA. Thereby, the display device 100 can be provided that has a structure in which the first electronic device 11 and/or the second electronic device 12 disposed under, at a lower portion of, the display panel 110 efficiently receive light while maintaining the characteristics of light emitting areas EA included in the display device 100.

The light transmissive enhancement layer 600 may be disposed to overlap with the bank BK and the encapsulation layer ENCAP.

The light transmissive enhancement layer 600 may include an organic material or an inorganic material. For example, the light transmissive enhancement layer 600 may include one or more organic materials selected from TPD, NPB, Bebq2, DMQA, or Coumarin derivatives. In another example, the light transmissive enhancement layer 600 may include one or more inorganic materials selected from silicon oxynitride (SiON), silicon nitride (SiNx), zinc sulfide (ZnS), or aluminum oxide (AlOx).

For example, the light transmissive enhancement layer 600 may be in the form of one layer or a plurality of layers.

The light transmissive enhancement layer 600 may have a refractive index in the range of 1.4 to 3.5 and a thickness of 5 to 300 nm.

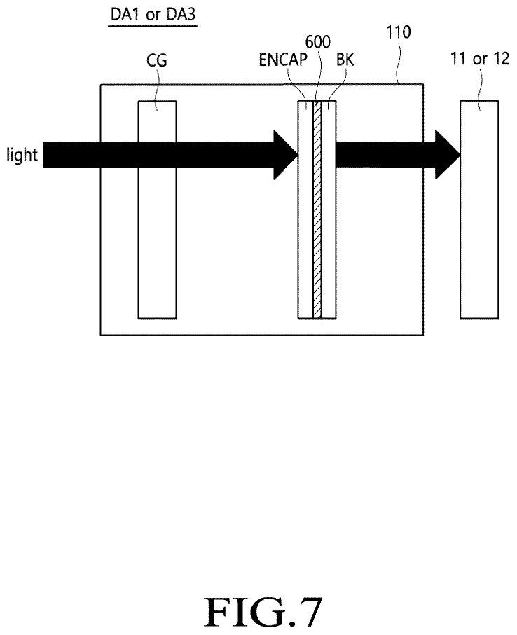

FIG. 7 illustrates an example situation of the first display area DA1 or the third display area DA3 allowing light to be transmitted in the display panel 110 according to aspects of the present disclosure.

Herein, the transmission, passing, or traveling of light through the optical area may mean that light enters the front surface of the display panel 110, passes through the display panel 110, and exits the back surface of the display panel 110.

Light may enter the front surface (the viewing surface) of the display panel 110, pass through the display panel 110, reach one or more electronic devices (11 and/or 12) located under, or at the lower portion of, the display panel 110 (the opposite side of the viewing surface). Light passing through the display panel 110 may include, for example, visible light, ultraviolet light, or the like.

For example, light can pass through a cover glass CG of the display panel 110, and then pass through the light transmissive enhancement layer 600 between the encapsulation layer ENCAP and the bank BK.

The one or more electronic devices (11 and/or 12) may be devices capable of receiving or detecting light passing through the display panel 110 and perform a predefined function based on the received light. It should be noted that even though the one or more electronic devices (11 and/or 12) are devices that need to receive light, the one or more electronic devices (11 and/or 12) may be located on the back of the display panel 110 (e.g., on an opposite side of the viewing surface thereof), and thereby, may receive light passing through the display panel 110.

For example, the first electronic device 11 may perform a predetermined operation using the first wavelength light, and the second electronic device 12 may perform a predetermined operation using the second wavelength light different from the first wavelength light.

The first wavelength may include one or more of a wavelength band of visible light, a wavelength band of infrared light, and a wavelength band of ultraviolet light. The second wavelength may include one or more of a wavelength band of visible light, a wavelength band of infrared light, a wavelength band of ultraviolet light, and the like, but may be different from the first wavelength.

The light transmissive enhancement layer 600 may help the light transmittance of the display panel to increase so that the first electronic device 11 and/or the second electronic device 12 can effectively receive or detect light.

For example, the one or more electronic devices (11 and/or 12) may include one or more of the following: an image capture device such as a camera, an image sensor, and/or the like; or a sensor such as a proximity sensor, an illuminance sensor, and/or the like. For example, the sensor may be an infrared sensor that performs a predetermined operation using infrared light.

For example, the first electronic device 11 may be a sensor such as a proximity sensor, an illuminance sensor, an infrared sensor, or the like, and the second electronic device 12 may be a camera, an image sensor, or the like. For example, the sensor may be an infrared sensor capable of detecting infrared light. In another example, the first electronic device 11 may be a camera, an image sensor, or the like, and the second electronic device 12 may be a sensor such as a proximity sensor, an illuminance sensor, an infrared sensor, or the like.

Hereinafter, discussions are provided based on examples where the first electronic device 11 is an infrared sensor capable of receiving infrared light and performing a predetermined operation, and the second electronic device 12 is a camera capable of receiving visible light and performing a predetermined operation.

The first electronic device 11 can perform the predetermined operation using light of wavelengths different from wavelengths light emitted from a light emitting element. The second electronic device 12 can perform the predetermined operation using light of the same wavelengths as wavelengths of light emitted from a light emitting element.

Hereinafter, discussions are provided based on an example where a light transmissive enhancement layer 600 is disposed in the first display area DA1 to improve an infrared reception rate of the first electronic device 11.

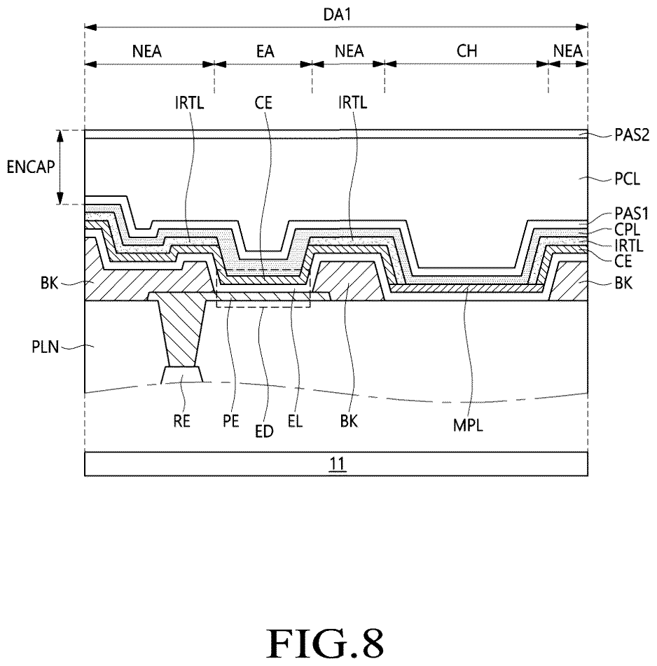

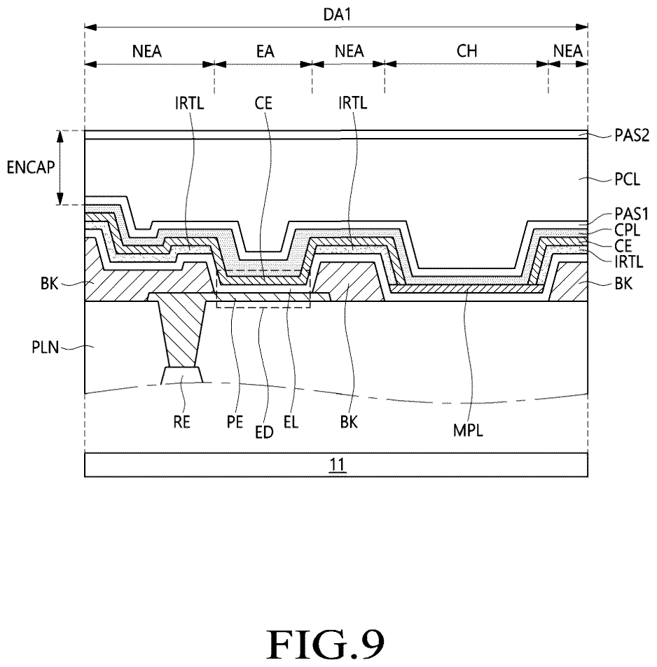

FIGS. 8 and 9 are example cross-sectional views of the first display area DA1 in the display panel 110 according to aspects of the present disclosure. Hereinafter, discussions for the configurations of FIGS. 8 and 9 are provided with reference to FIG. 6 together, and discussions for features equal, substantially equal, or similar to the features described with reference to FIG. 6 are omitted for simplicity.

In one or more example embodiments, the first display area DA1 defined in the display panel 110 may include an area in which a non-light emitting area NEA, light emitting areas EA, and common electrode holes CH are disposed.

The first electronic device 11 capable of performing a predetermined operation using infrared light may be disposed under a substrate in the first optical area DA1.

The light emitting areas EA may be areas in which light emitting elements ED each including a pixel electrode PE, an intermediate layer EL, and a common electrode CE are disposed. The non-light emitting area NEA may be an area in which a light emitting element ED including a pixel electrode PE, an intermediate layer EL, and a common electrode CE is not disposed.

The intermediate layer EL may include an emission layer.

A bank BK may be disposed on the pixel electrode PE, and a portion of the pixel electrode PE may be exposed through an opening of the bank BK. For example, the opening of the bank BK may overlap with a portion of the pixel electrode PE.

In one or more aspects, the bank BK may further include openings overlapping with common electrode holes CH.

The intermediate layer EL may be disposed on the bank BK. The intermediate layer EL may contact the portion of the pixel electrode PE through the opening of the bank BK.

The encapsulation layer ENCAP may include a first encapsulation layer PAS1, a second encapsulation layer PCL, and a third encapsulation layer PAS2. For example, the first encapsulation layer PAS1 and the third encapsulation layer PAS2 may be inorganic layers, and the second encapsulation layer PCL may be an organic layer.

A capping layer CPL may be disposed between the common electrode CE and the encapsulation layer ENCAP. The capping layer CPL can serve to reduce light loss occurring when light emitted from the emission layer is repeatedly reflected by the common electrode CE and the pixel electrode PE, and protect the light emitting element ED from ultraviolet light during the process of curing the encapsulation layer ENCAP.

The capping layer CPL may be disposed in a whole area where the non-light emitting area NEA, the light emitting areas EA, and the common electrode holes CH are disposed in the first display area DA1.

Referring to FIGS. 8 and 9, an infrared transmissive layer IRTL, which is a type of light transmissive enhancement layer 600, may be disposed in the first display area DA1 to overlap with at least a portion of the first display area DA1. The infrared transmissive layer IRTL can serve to improve an infrared reception rate of the first electronic device 11 configured to perform a predetermined operation using infrared light.

For example, the infrared transmissive layer IRTL can minimize a decrease in infrared transmittance caused by the common electrode CE. An infrared transmittance of the infrared transmissive layer IRTL may be greater than an infrared transmittance of the common electrode CE.

Referring to FIG. 8, the infrared transmissive layer IRTL may be disposed between the common electrode CE and the encapsulation layer ENCAP. For example, the infrared transmissive layer IRTL may be disposed between the common electrode CE and the capping layer CPL, and the capping layer CPL may be disposed between the infrared transmissive layer IRTL and the encapsulation layer ENCAP. In one or more aspects, the infrared transmissive layer IRTL may be disposed such that it overlaps with the common electrode CE and the bank BK.

Referring to FIG. 9, the infrared transmissive layer IRTL may be disposed between the common electrode CE and the bank BK. In one or more aspects, the infrared transmissive layer IRTL may be disposed such that it overlaps with the common electrode CE and the bank BK.

In an example where the infrared transmissive layer IRTL, which is a type of light transmissive enhancement layer, is in contact with the common electrode CE, infrared transmittance can be effectively increased by reducing infrared reflection that may appear at the common electrode CE. Therefore, referring to FIGS. 8 and 9, at least a portion of the common electrode CE may be in contact with the infrared transmissive layer IRTL.

Referring to FIGS. 8 and 9, the infrared transmissive layer IRTL may not overlap with an opening of the bank BK overlapping with the common electrode hole CH.

Since the infrared transmissive layer IRTL is disposed to not overlap with the light emitting element ED, the light emitting area EA may not be affected by the infrared transmissive layer IRTL. For example, as the infrared transmissive layer IRTL is disposed in an area other than the light emitting area EA, an infrared transmittance in the first display area DA1 can be improved without any reduction in image quality due to the infrared transmissive layer IRTL.

In this configuration, the infrared transmissive layer IRTL may be disposed in the first display area DA1 such that the infrared transmissive layer IRTL has an opening overlapping with the light emitting area EA.

A plurality of common electrode holes CH may be disposed in the first display area DA1. A respective area where each common electrode hole CH is disposed may overlap with a corresponding one of openings of the bank BK, and a metal patterning layer MPL may be disposed in the common electrode holes CH.

Referring to FIGS. 8 and 9, the infrared transmissive layer IRTL may be disposed such that it does not overlap with the metal patterning layer MPL.

The infrared transmissive layer IRTL may have an opening overlapping with the common electrode hole CH.

In one or more aspects, the infrared transmissive layer IRTL may include a plurality of layers to further improve infrared transmittance. In this configuration, each of the plurality of layers may be an organic layer or an inorganic layer.

For example, the infrared transmissive layer IRTL may include one or more organic materials selected from TPD, NPB, Bebq2, DMQA, or Coumarin derivatives. In another example, the infrared transmissive layer IRTL may include one or more inorganic materials selected from silicon oxynitride (SiON), silicon nitride (SiNx), zinc sulfide (ZnS), or aluminum oxide (AlOx).

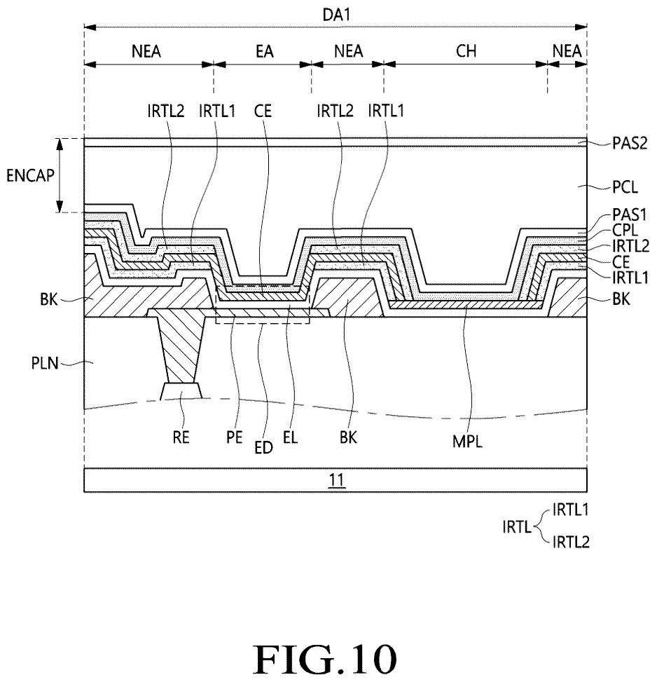

FIG. 10 is an example cross-sectional view of the first display area DA1 in the display panel 110 according to aspects of the present disclosure. Hereinafter, discussions for the configuration of FIG. 10 are provided with reference to FIGS. 6 and 8 together, and discussions for features equal, substantially equal, or similar to the features described with reference to FIGS. 6 and 8 are omitted for simplicity.

Referring to FIG. 10, in one or more example embodiments, an infrared transmissive layer IRTL, which is a type of light transmissive enhancement layer 600, may include a first infrared transmissive layer IRTL1 and a second infrared transmissive layer IRTL2.

In this configuration, the first infrared transmissive layer IRTL1 may be disposed between a common electrode CE and a bank BK, and the second infrared transmissive layer IRTL2 may be disposed between the common electrode CE and a capping layer CPL.

When the infrared transmissive layer IRTL is in contact with the common electrode CE, infrared reflection that may appear at the common electrode CE may be effectively reduced, and thereby, infrared transmittance can be increased. Therefore, referring to FIG. 10, at least a portion of the common electrode CE may be in contact with the first infrared transmissive layer IRTL1 and/or the second infrared transmissive layer IRTL2.

Since the first infrared transmissive layer IRTL1 and the second infrared transmissive layer IRTL2 are disposed not to overlap with a light emitting element ED, light emitted from a corresponding light emitting area EA may not be affected by the first infrared transmissive layer IRTL1 and the second infrared transmissive layer IRTL2. For example, since both the first infrared transmissive layer IRTL1 and the second infrared transmissive layer IRTL2 are disposed in an area other than the light emitting area EA, infrared transmittance in the first display area DA1 can be improved without a decrease in image quality due to the infrared transmissive layer IRTL.

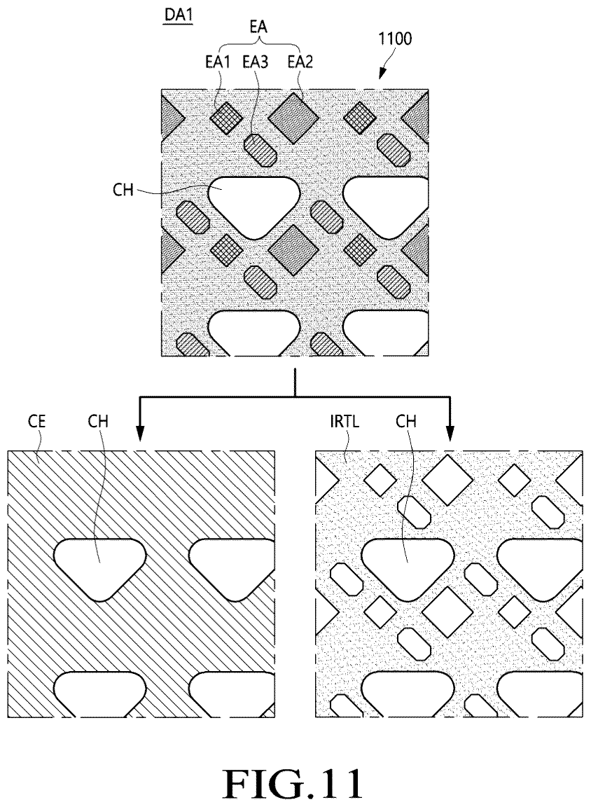

Hereinafter, with reference to FIG. 11, the configuration of the display device 100 in a plan view is discusses in detail.

FIG. 11 is a plan view of an example partial area 1100 of the first display area DA1 in the display panel 110 according to aspects of the present disclosure.

In FIG. 11, a common electrode CE and an infrared transmissive layer IRTL in a portion 1100 of the first display area DA1 are separately shown.

The first display area DA1 may include a plurality of light emitting areas EA.

The plurality of light emitting areas EA disposed in the first display area DA1 may include at least one first color light emitting area EA1 emitting light of a first color, at least one second color light emitting area EA2 emitting light of a second color, and at least one third color light emitting area EA3 emitting light of a third color. At least one of the first color light emitting area EA1, the second color light emitting area EA2, and the third color light emitting area EA3 may have an area different from the one or more remaining light emitting areas. The first color, the second color, and the third color may be different colors from each other, and may be various colors. For example, the first color, second color, and third color may be or include red, green, and blue, respectively.

A plurality of common electrode holes CH may be disposed in the first display area DA1. A respective area where each common electrode hole CH is disposed may overlap with a corresponding one of openings of the bank BK, and a metal patterning layer may be disposed in the common electrode holes CH.

Referring to FIG. 11, in the portion 1100 of the first display area DA1, since the common electrode CE may be disposed in all of the light emitting areas EA and a portion of the non-light emitting area except for the common electrode holes CH, when the common electrode CE in the portion 1100 of the first display area DA1 is separately shown, the common electrode CE may be shown such that the common electrode CE has openings (i.e., empty spaces) only in areas where the common electrode holes CH are disposed.

In the portion 1100 of the first display area DA1, the infrared transmissive layer IRTL may be disposed not to overlap with the light emitting areas EA. Referring to FIG. 11, in an example where the infrared transmissive layer IRTL is disposed not to overlap with the common electrode hole CH as illustrated in FIGS. 8 to 10, when the infrared transmissive layer IRTL in the portion 1100 of the first display area DA1 is separately shown, the infrared transmissive layer IRTL may be shown such that the infrared transmissive layer IRTL has openings (i.e., empty spaces) in the light emitting areas EA and areas where the common electrode holes CH are disposed.

Therefore, the infrared transmissive layer IRTL may not interfere with light emitted from the light emitting areas EA. For example, an infrared transmittance in the first display area DA1 may be improved without changing the resolution or the number of subpixels due to the infrared transmissive layer IRTL in the light emitting areas EA.

In this configuration, referring to FIG. 8, the infrared transmissive layer IRTL may be disposed, for example, between the capping layer CPL and the common electrode CE in the non-light emitting area NEA. In another example, referring to FIG. 9, the infrared transmissive layer IRTL may be disposed between the common electrode CE and the bank BK in the non-light emitting area NEA. In another example, referring to FIG. 10, the infrared transmissive layer IRTL may be disposed both between the capping layer CPL and the common electrode CE and between the common electrode CE and the bank BK in the non-light emitting area NEA.

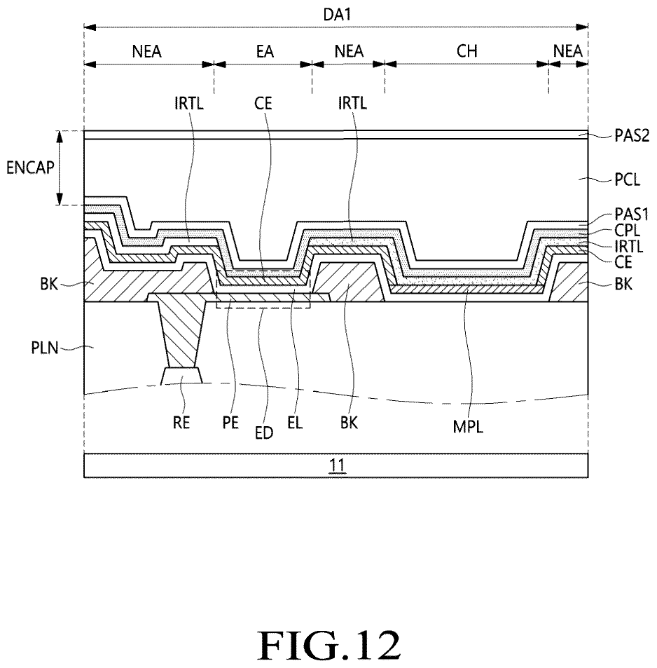

FIG. 12 is an example cross-sectional view of the first display area DA1 in the display panel 110 according to aspects of the present disclosure. Hereinafter, discussions for the configuration of FIG. 12 are provided with reference to FIGS. 6 and 8 together, and discussions for features equal, substantially equal, or similar to the features described with reference to FIGS. 6 and 8 are omitted for simplicity.

In one or more example embodiments, the first display area DA1 defined in the display panel 110 may include an area in which a non-light emitting area NEA, light emitting areas EA, and common electrode holes CH are disposed.

The first electronic device 11 capable of performing a predetermined operation using infrared light may be disposed under a substrate in the first optical area DA1.

A capping layer CPL may be disposed between a common electrode CE and an encapsulation layer ENCAP. The capping layer CPL can serve to reduce light loss occurring when light emitted from an emission layer is repeatedly reflected by the common electrode CE and a pixel electrode PE, and protect a light emitting element ED from ultraviolet light during the process of curing the encapsulation layer ENCAP.

The capping layer CPL may be disposed in a whole area where the non-light emitting area NEA, the light emitting area areas EA, and the common electrode holes CH are disposed in the first display area DA1.

Referring to FIG. 12, an infrared transmissive layer IRTL, which is a type of light transmissive enhancement layer, may be disposed between the common electrode CE and the capping layer CPL, and the capping layer CPL may be disposed between the infrared transmissive layer IRTL and the encapsulation layer ENCAP. For example, the infrared transmissive layer IRTL may be disposed such that it overlaps with the common electrode CE and a bank BK.

In another example, the infrared transmissive layer IRTL may be disposed between the common electrode CE and the bank BK. For example, the infrared transmissive layer IRTL may include a plurality of layers, and each of the plurality of layers may be an organic layer or an inorganic layer.

When the infrared transmissive layer IRTL, which is a type of light transmissive enhancement layer, is in contact with the common electrode CE, infrared transmittance can be effectively increased by reducing infrared reflection that may appear in the common electrode CE. Therefore, referring to FIG. 12, at least a portion of the common electrode CE may be in contact with the infrared transmissive layer IRTL.

To pattern the common electrode CE, a metal patterning layer MPL may be disposed in common electrode hole CH. The metal patterning layer MPL may have various shapes, such as a circle, an oval, and an octagon. After the metal patterning layer MPL is disposed, the common electrode CE may be disposed.

Unlike those illustrated in FIGS. 8 to 10, referring to FIG. 12, the infrared transmissive layer IRTL disposed in the first display area DA1 may overlap with the metal patterning layer MPL disposed in the common electrode hole CH. For example, the infrared transmissive layer IRTL may also be disposed in the common electrode hole CH.

When the infrared transmissive layer IRTL, which is a type of light transmissive enhancement layer, is disposed in the common electrode hole CH, an infrared transmittance in the common electrode hole CH can be more increased compared with an example where the infrared transmissive layer IRTL is not disposed in the common electrode hole CH.

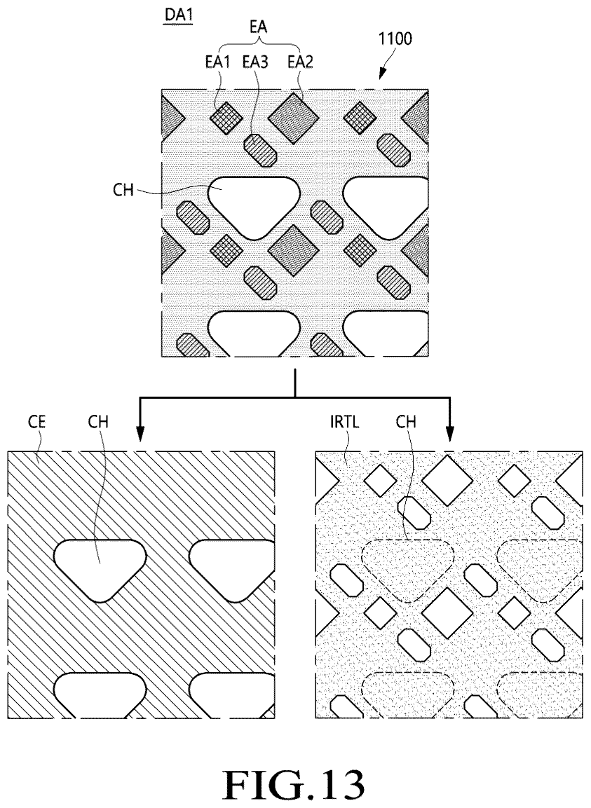

FIG. 13 is an example plan view of the portion 1100 of the first display area DA1 in the display panel 110 according to aspects of the present disclosure. Hereinafter, discussions for the configuration of FIG. 13 are provided, and discussions for features equal, substantially equal, or similar to the features described with reference to FIG. 11 are omitted for simplicity.

Referring to FIG. 13, in one or more example embodiments, the first display area DA1 may include light emitting areas EA and common electrode holes CH. A metal patterning layer may be disposed in the common electrode holes CH.

Referring to FIG. 13, in the portion 1100 of the first display area DA1, since a common electrode CE may be disposed in all of the light emitting areas EA and a portion of the non-light emitting area except for the common electrode holes CH, when the common electrode CE in the portion 1100 of the first display area DA1 is separately shown, the common electrode CE may be shown such that the common electrode CE has openings (i.e., empty spaces) only in areas where the common electrode holes CH are disposed.

In the portion 1100 of the first display area DA1, an infrared transmissive layer IRTL, which is a type of light transmissive enhancement layer, is disposed not to overlap with the light emitting areas EA, a sensor disposed under, or at a lower portion of, the display panel 110 can efficiently receive or detect light, and the characteristics of the light emitting areas included in the display device 100 can be maintained. As illustrated in FIG. 12, when the infrared transmissive layer IRTL is disposed in the common electrode holes CH, when the infrared transmissive layer IRTL in the portion 1100 of the first display area DA1 1100 is separately shown, the infrared transmissive layer IRTL may be shown such that the infrared transmissive layer IRTL has openings (i.e., empty spaces) in the light emitting areas EA but does not have an opening in the common electrode holes CH.

In this configuration, referring to FIG. 12, the infrared transmissive layer IRTL may be disposed, for example, between the capping layer CPL and the common electrode CE in the non-light emitting area NEA. In another example, the infrared transmissive layer IRTL may be disposed between the common electrode CE and the bank BK in the non-light emitting area NEA.

Referring to FIG. 12, the infrared transmissive layer IRTL may be disposed to overlap with the metal patterning layer MPL in the common electrode hole CH.

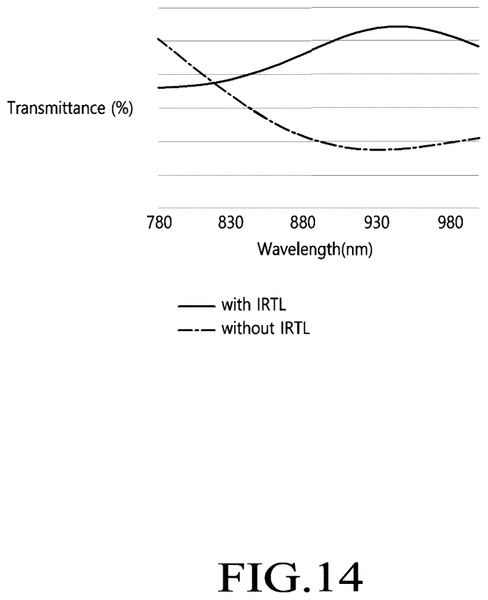

FIG. 14 illustrates example light transmittances of the display panel 110 according to wavelengths of light transmitted through the first display area DA1 in the display panel 110 including an infrared transmissive layer IRTL and the display panel 110 not including an infrared transmissive layer IRTL according to aspects of the present disclosure.

Referring to FIG. 14, it can be seen that a transmittance of infrared light (e.g., infrared light having wavelengths in the range of 780 nm to 1,000 nm) transmitted through the first display area DA1 in the display panel 110 including an infrared transmissive layer IRTL, which is a type of light transmissive enhancement layer, is greater than a transmittance of infrared light transmitted through the first display area DA1 in the display panel 110 not including the infrared transmissive layer IRTL.

Accordingly, the first electronic device 11 overlapping with the first display area DA1 and performing a predetermined operation using infrared light can have a greater infrared reception rate compared with an example where the infrared transmissive layer IRTL is not included. Thereby, the display device 110 can provide an advantage of being driven at low power because the first electronic device 11 can detect infrared light more effectively.

As described above, the infrared transmissive layer have been provided based on a configuration where the light transmissive enhancement layer is applied to the first display area DA1 overlapping with the first electronic device 11. Herein, the display device 100 having the structure where the first electronic device 11, for example, an infrared sensor is located under, or at a lower portion of, the display panel 110 without being exposed to the outside may be referred to as a display to which under-display infrared radiation (UDIR) technology is applied.

In one or more aspects, the display device 100 having the structure where the second electronic device 12, for example, a camera is located under, or at a lower portion of, the display panel 110 without being exposed to the outside may be referred to as a display to which under-display camera (UDC) technology is applied. In this configuration, the light transmissive enhancement layer may be applied to the third display area DA3 overlapping with the second electronic device 12. In this implementation, the second electronic device 12 may be an electronic device capable of performing a predetermined operation using light of the same wavelengths as light emitted from light emitting elements, and a light transmissive enhancement layer can serve to increase light transmittance in the range of wavelengths of visible light.

In the display device 100 to which both UDIR and UDC technologies are applied, the light transmissive enhancement layer may be disposed in both the first display area DA1 at least partially overlapping with the first electronic device 11 and the third display area DA3 at least partially overlapping with the second electronic device 12.

In one or more aspects, the second electronic device 12 configured to perform a predetermined operation using visible light may be disposed in an area where the display panel 110 is omitted. For example, a part of the display panel may be penetrated in a thickness direction (e.g., the vertical direction in a cross-sectional view) to form a hole, and the second electronic device 12 may be disposed in this hole. In this configuration, the display device 100 may be referred to as a display device to which hole-in active area (HiAA) technology is applied. In this implementation, a subpixel may not be disposed in the hole overlapping at least partially with the second electronic device 12, and therefore, the area of the hole may be a portion of the non-display area NDA. When the HiAA technology is applied to the second electronic device 12, a light transmissive enhancement layer may be applied as an infrared transmissive layer in the first display area DA1 where the first electronic device 11 is disposed, and may not be applied to a portion of the non-display area NDA where the second electronic device 12 is disposed.

According to the one or more examples, aspects and embodiments described above, the display device 100 can provide advantages of improving the transmittance of light passing through the display panel 110 and improving the reception rate of the at least one electronic device (11 and/or 12) located under the substrate.

In one or more examples, a wavelength may include one or more wavelengths. In one or more examples, a first wavelength may include one or more wavelengths. In one or more examples, a second wavelength may include one or more wavelengths.

The examples, aspects, and embodiments for the display device 100 and the display panel 110 described herein may be described as follows.

According to the one or more example embodiments described herein, a display device can be provided that includes a substrate, and a display area configured to display an image. The display area may include a first display area and a second display area located outside of the first display area, and the second display area may have a lower light transmittance for light of a first wavelength than the first display area. The display device may further include a pixel electrode disposed on the substrate and located in the first display area, a bank disposed on the pixel electrode and having a first opening exposing a portion of the pixel electrode, an emission layer disposed on the pixel electrode, a common electrode disposed on the emission layer, an encapsulation layer disposed on the common electrode, a light transmissive enhancement layer overlapping with the bank and the encapsulation layer and disposed between the bank and the encapsulation layer. At least a portion of the common electrode may contact the light transmissive enhancement layer.

In one or more aspects, a capping layer may be disposed between the light transmissive enhancement layer and the encapsulation layer.

In one or more aspects, the light transmissive enhancement layer may include an inorganic material and/or an organic material.

In one or more aspects, the light transmissive enhancement layer may include a plurality of layers, and each of the plurality of layers may be an organic layer or an inorganic layer.

In one or more aspects, the first display area may include a plurality of light emitting elements including the pixel electrode, the emission layer, and the common electrode. In one or more aspects, the light transmissive enhancement layer may not overlap with the plurality of light emitting elements, and the first wavelength may be different from wavelengths of light emitted from the light emitting elements. In one or more aspects, the first wavelength may be the same as a wavelength of light emitted from the light emitting elements.

In one or more aspects, the light transmissive enhancement layer may include a first light transmissive enhancement layer and a second light transmissive enhancement layer. In one or more aspects, the first light transmissive enhancement layer may be disposed between the common electrode and the bank, and the second light transmissive enhancement layer may be disposed between the common electrode and the encapsulation layer.

In one or more aspects, the common electrode may include a plurality of holes, and a metal patterning layer may be disposed in the plurality of holes of the common electrode. In one or more aspects, the bank may include second openings overlapping with the plurality of holes of the common electrode, and the light transmissive enhancement layer may not overlap with the second openings of the bank.

In one or more aspects, the display device further including an electronic device located under the substrate, overlapped with the first display area, and performing a predetermined operation using the first wavelength light.

According to the one or more example embodiments described herein, a display device can be provided that includes a substrate, a common electrode disposed on a substrate, and an infrared transmissive layer disposed on the substrate, overlapping with at least a portion of the common electrode, and having greater infrared transmittance than the common electrode. In one or more aspects, the display device may include a display area in which an image is displayed, and the display area may include a first display area in which a common electrode hole is formed, and a second display area located outside of the first display area and not having the common electrode hole. In one or more aspects, the first display area may include light emitting areas including light emitting elements, and the infrared transmissive layer may be disposed in the first display area and have a first opening overlapping with a corresponding one of the light emitting areas.

In one or more aspects, at least a portion of the common electrode may contact the infrared transmissive layer.

In one or more aspects, the infrared transmissive layer may have an opening overlapping with the common electrode hole.

In one or more aspects, the display device may include a metal patterning layer disposed in the common electrode hole and overlapped with the infrared transmissive layer. In one or more aspects, the infrared transmissive layer may not overlap with the metal patterning layer.

According to the one or more aspects described herein, a display device may be provided that includes a light transmissive structure of enabling at least one device located under, at a lower portion of, a display panel to effectively receive light (e.g., visible light, infrared light, ultraviolet light, or the like) while not being exposed in a front surface of the display device.

According to the one or more aspects described herein, a display device may be provided that includes a light transmissive enhancement layer capable of increasing light transmittance even in an area of the common electrode where a hole is not present.

According to the one or more aspects described herein, a display device may be provided that includes a structure of enabling a detection sensor located under, or at a lower portion of, a display panel to efficiently receive light while maintaining the light emitting area characteristics of the display device.

According to the one or more aspects described herein, a display device may be provided that includes a structure of enabling an infrared sensor located under, or at a lower portion of, a display panel to efficiently receive infrared light through an infrared transmissive layer, which is a type of light transmissive enhancement layer.

According to the one or more aspects described herein, a display device may be provided that is capable of improving the efficiency of an electronic device by increasing the amount of light incident on the electronic device included in a display device without additional power consumption, and thereby, enabling the display device to be driven at low power.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the principles described herein may be applied to other embodiments and applications without departing from the scope of the present disclosure. The above description and the accompanying drawings provide an example of the technical idea of the present disclosure for illustrative purposes only. That is, the disclosed embodiments are intended to illustrate the scope of the technical idea of the present disclosure. The scope of protection of the present disclosure should be construed based on the following claims, and all technical features within the scope of equivalents thereof should be construed as being included within the scope of the present disclosure.

What is claimed is:

1. A display device, comprising:
a substrate;
a display area configured to display an image, wherein the display area comprises a first display area and a second display area located outside of the first display area, and the second display area is configured to have a lower light transmittance for light of a first wavelength than the first display area;
a pixel electrode disposed on the substrate and located in the first display area;
a bank disposed on the pixel electrode and having a first opening exposing a portion of the pixel electrode;
an emission layer disposed on the pixel electrode;
a common electrode disposed on the emission layer;
an encapsulation layer disposed on the common electrode; and
a light transmissive enhancement layer overlapping with the bank and the encapsulation layer and disposed between the bank and the encapsulation layer,
wherein at least a portion of the common electrode contacts the light transmissive enhancement layer.

2. The display device of claim 1, further comprising a capping layer disposed between the light transmissive enhancement layer and the encapsulation layer.

3. The display device of claim 1, wherein the first display area comprises a plurality of light emitting elements including the pixel electrode, the emission layer, and the common electrode, and the light transmissive enhancement layer does not overlap with the plurality of light emitting elements.

4. The display device of claim 3, wherein the first wavelength is different from wavelengths of light emitted from the light emitting elements.

5. The display device of claim 3, wherein the first wavelength is same as a wavelength of light emitted from the light emitting elements.

6. The display device of claim 1, wherein the light transmissive enhancement layer comprises a first light transmissive enhancement layer disposed between the common electrode and the bank.

7. The display device of claim 1, wherein the light transmissive enhancement layer comprises a second light transmissive enhancement layer disposed between the common electrode and the encapsulation layer.

8. The display device of claim 2, wherein the light transmissive enhancement layer comprises:
a first light transmissive enhancement layer disposed between the common electrode and the capping layer; and
a second light transmissive enhancement layer disposed between the common electrode and the bank.

9. The display device of claim 1, wherein the common electrode comprises a plurality of holes, and a metal patterning layer is disposed in the plurality of holes of the common electrode.

10. The display device of claim 9, wherein at least a portion of the light transmissive enhancement layer overlaps with the metal patterning layer.

11. The display device of claim 9, wherein the light transmissive enhancement layer does not overlap with the metal patterning layer.

12. The display device of claim 9, wherein the bank further comprises second openings overlapping with the plurality of holes of the common electrode, and the light transmissive enhancement layer does not overlap with the second openings of the bank.

13. The display device of claim 1, further comprising an electronic device located under the substrate, overlapped with the first display area, and configured to perform a predetermined operation using the light of the first wavelength.

14. The display device of claim 1, wherein the light transmissive enhancement layer comprises an inorganic material.

15. The display device of claim 1, wherein the light transmissive enhancement layer comprises an organic material.

16. The display device of claim 1, wherein the light transmissive enhancement layer comprises a plurality of layers, and each of the plurality of layers is an organic layer or an inorganic layer.

17. A display device, comprising:
a substrate;
a common electrode disposed on the substrate; and
an infrared transmissive layer disposed on the substrate, overlapping with at least a portion of the common electrode, and having a greater infrared transmittance than the common electrode,
wherein the display device comprises a display area configured to display an image, and the display area comprises a first display area in which a common electrode hole is formed, and a second display area located outside of the first display area and not having the common electrode hole,
wherein the first display area comprises light emitting areas including light emitting elements, and
wherein the infrared transmissive layer is disposed in the first display area and has a first opening overlapping with a corresponding one of the light emitting areas.

18. The display device of claim 17, further comprising a capping layer disposed on the common electrode,
wherein the infrared transmissive layer is disposed between the common electrode and the capping layer.

19. The display device of claim 17, wherein the infrared transmissive layer has a second opening overlapping with the common electrode hole.

20. The display device of claim 17, further comprising a metal patterning layer disposed in the common electrode hole and overlapped with the infrared transmissive layer.
